(19) United States
(12) Patent Application Publication
(10) Pub. No.: US 2015/0282317 A1
(43) Pub. Date: Oct. 1, 2015

(54) EDGE CONTACTS OF CIRCUIT BOARDS, AND RELATED APPARATUS AND METHODS

(71) Applicant: Lockheed Martin Corporation, Bethesda, MD (US)

(72) Inventors: Stephen Gonya, Endicott, NY (US); Timothy J. Dougherty, Endicott, NY (US); Jeffrey Fisher, Endwell, NY (US); Michael Hochdoerfer, Vestal, NY (US); Kenneth R. Twigg, Sayre, PA (US); Eugene J. Urda, Binghamton, NY (US)

(73) Assignee: Lockheed Martin Corporation, Bethesda, MD (US)

(21) Appl. No.: 14/228,866

(22) Filed: Mar. 28, 2014

(51) Int. Cl. H05K 1/11; H05K 3/00; H05K 3/46; H05K 1/02

(52) U.S. Cl. CPC H05K 1/115; H05K 1/0298; H05K 3/0094; H05K 3/46; H05K 2201/09509; H05K 2201/09536

(57) ABSTRACT

In some embodiments, flat electrical contact pads may be fabricated along a routed edge face of a printed wiring board (PWB). Some embodiments of the edge pads may, for example, be perpendicular to a plane of the printed wiring board. In some embodiments, the edge pads may be of a specified length and/or width. Some embodiments of the edge pads may, for example, have a surface finish suitable for soldering and/or for direct contact interconnections. In some embodiments, the edge pads may, for example, be configured for electrical connection to an adjoining device (e.g., PWB) with mating pads to form a tiled array configuration of interconnected devices (e.g., PWBs).

### BACKGROUND

1. Field

The technology described herein relates generally to edge contacts of circuit boards, and related apparatus and methods.

2. Related Art

Many electronic systems use circuit boards to interconnect various electronic devices. A circuit board typically includes at least one substrate layer and at least one conductive layer. A substrate layer may support electronic devices disposed on the circuit board, and/or insulate conductive layers from each other. A conductive layer may include conductive traces for carrying signals on that layer of the circuit board.

Multi-layer circuit boards may include vias for carrying signals between different layers of the circuit board. A “through-hole via” typically connects the top and bottom surfaces of a circuit board, such that the via's ends are exposed at both the top and bottom surfaces of the circuit board. A “blind via” is a type of microvia which typically connects the top or bottom surface of a circuit board to an interior layer of the circuit board, such that the via's end is exposed at a top or bottom surface of the circuit board, but not both. A “buried via” is a type of microvia which typically connects interior layers of the circuit board, such that the via's ends are not exposed at the top or bottom surface of the circuit board.

A circuit board may include one or more input/output terminals. An input/output terminal may be disposed on a top or bottom surface of the circuit board, or at an edge of the circuit board. An input/output terminal disposed at an edge of a circuit board may be referred to as an “edge contact.” Conventional edge contacts are typically castellated.

### BRIEF DESCRIPTION OF THE DRAWINGS

Various aspects and embodiments of the disclosure are described with reference to the following figures. It should be appreciated that the figures are not necessarily drawn to scale. Items appearing in multiple figures are indicated by the same reference number in all the figures in which they appear.

FIG. 1 is a perspective view of a portion of a circuit board with an edge contact, in accordance with some embodiments;

FIG. 2 is a perspective view of a portion of a circuit board with an edge contact, in accordance with some embodiments;

FIG. 3 is a perspective view of a portion of a circuit board with an edge contact, in accordance with some embodiments;

FIG. 4 is a flowchart of a process for manufacturing a circuit board with an edge contact, in accordance with some embodiments;

FIG. 5A is a perspective view of a portion of a circuit board with a through hole, in accordance with some embodiments;

FIG. 5B is a side view of the portion of the circuit board illustrated in FIG. 5A;

FIG. 6A is a perspective view of a portion of a circuit board with a via, in accordance with some embodiments;

FIG. 6B is a side view of the portion of the circuit board illustrated in FIG. 6A;

FIG. 7A is a perspective view of a portion of a circuit board with an edge contact, in accordance with some embodiments; and

FIG. 7B is a side view of the portion of the circuit board illustrated in FIG. 7A.

### SUMMARY

In some embodiments, a circuit board is provided, comprising a plurality of layers stacked in a thickness direction, a peripheral edge having a first thickness in the thickness direction, and an edge contact disposed at the peripheral edge of the circuit board. The edge contact has a second thickness in the thickness direction. The second thickness is less than the first thickness.

In some embodiments, a method of manufacturing a circuit board is provided , comprising at least partially filling a hole with a conductive material. The hole extends through one or more layers of material. The method further comprises using the one or more layers of material to form a multilayer circuit board with at least one end of the hole covered by a layer of material, and forming an edge contact by exposing a portion of the conductive material at a peripheral edge of the multilayer circuit board.

### DETAILED DESCRIPTION

The geometry (e.g., height, length, width, shape, etc.) of traces, vias, and/or input/output terminals may affect the quality of a circuit board's signals, such as high-frequency signals. In some applications, such as processing of sensor signals, the impact of edge contact geometry on signal quality can be significant. The inventors have recognized and appreciated that conventional techniques for forming edge contacts on circuit boards do not permit sufficient control over the geometry of the edge contact, making it difficult or impossible to maintain desired signal quality for some applications, such as sensor applications. For example, conventional edge contacts extend through the entire thickness of the circuit board, such that the thickness of the edge contact is dictated by the thickness of the circuit board, even when the thickness of the circuit board is smaller or greater than the desired thickness of the edge contact.

Thus, forming an edge contact with a thickness that is less than the thickness of the circuit board's peripheral edge may improve signal quality. The edge contact may extend to the bottom of the peripheral edge without extending to the top, or extend to the top of the peripheral edge without extending to the bottom, or extend to neither the top nor the bottom of the peripheral edge. Such an edge contact may be manufactured by forming a microvia (e.g,. buried or blind via) in a circuit board, and routing the circuit board to form the peripheral edge through the microvia.

The various aspects described above, as well as further aspects, are described in further detail below. It should be appreciated that these aspects may be used alone, all together, or in any combination of two or more, to the extent that they are not mutually exclusive.

As used herein, “circuit board” may include, but is not limited to, a printed circuit board, a printed wiring board, an etched wiring board, a printed circuit assembly, a printed circuit board assembly, circuit card, circuit card assembly, backplane, backplane assembly, or any other structure suitable for mechanically supporting and/or electrically connecting traces, pins, contacts, pads, terminals, electrical components, electronic components, optoelectronic components, electromechanical components, integrated circuits (“chips”), and/or semiconductor devices.

### A Circuit Board with an Edge Contact

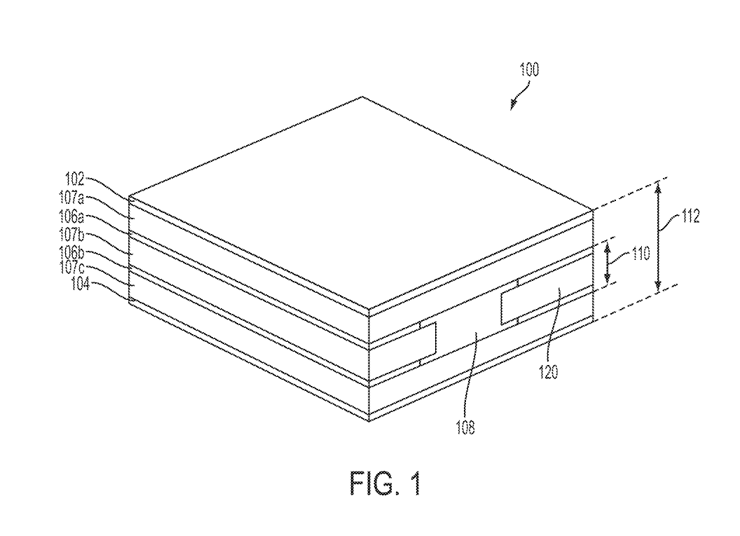

FIG. 1 shows a perspective view of a portion of a circuit board 100 with an edge contact 108, in accordance with some embodiments. Circuit board 100 includes seven layers (102, 104, 106a-b, and 107a-c). Top layer 102, bottom layer 104, and internal layers 106a-b may include conductive traces formed from one or more conductive materials, such as copper, gold, silver, or any other suitable electrical conductor. The conductive traces may interconnect various structures on the circuit board, such as contacts, vias, devices mounted on the circuit board, or any other suitable structures. A circuit board layer containing one or more conductive traces may be referred to herein as a “conductive layer.” Internal layers 107a-c may include a substrate that electrically insulates the conductive layers from each other, such as an FR4 substrate, a fiber glass laminate, and or any other suitable insulating material. Embodiments are not limited by the number, configuration, pattern, or composition of the layers of the circuit board.

Edge contact 108 is disposed at a peripheral edge 120 of circuit board 100. Methods of forming edge contacts, such as edge contact 108, are described below. In some embodiments, a peripheral edge may include one or more surfaces disposed between top and bottom surfaces of a circuit board at a periphery of the circuit board. Edge contact 108 may be configured to conductively couple one or more components of circuit board 100 and an electronic component external to circuit board 100. For example, edge contact 108 may be configured to conductively couple one or more traces, vias, contacts, and/or electronic devices of circuit board 100 with an external signal carrier (e.g., conductor), a contact of another circuit board, and/or a terminal of an external electronic device. In some embodiments, edge contact 108 may be configured to communicatively couple a processing circuit disposed on circuit board 100 to a sensor signal generated external to circuit board 108. In some embodiments, edge contact 108 may be configured to communicatively couple a terminal of a sensor device disposed on circuit board 100 to a processing circuit disposed external to circuit board 100. In some embodiments, edge contact 108 may be coupled to a processing circuit configured to control a sensor circuit. In some embodiments, edge contact 108 may operate as an input terminal (e.g., a terminal that receives signals generated externally to circuit board 100 and communicates the signals to a component of circuit board 100), an output terminal (e.g., a terminal that sends a signal from circuit board 100 to a component external to circuit board 100), or as an input/output terminal (e.g., a terminal that both sends and receives signals).

As shown in FIG. 1, the thickness 110 of edge contact 108 is less than the thickness 112 of peripheral edge 120. Edge contact 108 extends between internal conductive layers 106a and 106b, and through substrate layer 107b. The top end of edge contact 108 is covered by internal substrate layer 107a and top conductive layer 102. The bottom end of edge contact 108 is covered by internal substrate layer 107c and bottom conductive layer 104. When the top end of an edge contact is covered by at least one layer of a circuit board, and the bottom end of the edge contact is also covered by at least one layer of the circuit board, as in the case of edge contact 108 of FIG. 1, the edge contact may be referred to as a “buried edge contact.”

In some embodiments, an edge contact may extend between any two layers of a circuit board. In some embodiments, an edge contact may extend between any pair of layers of a circuit board other than the pair consisting of the top layer and the bottom layer of the circuit board. For example, an edge contact may extend between the top layer and any internal layer, or between the bottom layer and any internal layer, or between any two internal layers. In some embodiments, an edge contact may extend through one or more layers of a circuit board. In some embodiments, an edge contact may extend through one or more layers of a circuit board without extending through all layers of the circuit board. For example, an edge contact may be covered by a layer of the circuit board at a bottom end and exposed at a top layer of the circuit board, or be covered by a layer of the circuit board at a top end and exposed at a bottom layer of the circuit board, or be covered by a layer of the circuit board at a top end and at a bottom end.

Edge contact 108 may be manufactured, for example, by forming a buried via hole in one or more layers of a circuit board, at least partially filling the buried via hole with a conductive material, and cutting the circuit board through at least a portion of the via hole to expose the conductive material. In the embodiment of FIG. 1, edge contact 108 may be communicatively coupled to components of internal layers 106a and 106b. For example, the conductive material of edge contact 108 may be connected to conductive material (e.g., one or more traces) in internal layers 106a and 106b. In some embodiments, an edge contact may be communicatively coupled to one or more of the layers through which or between which the edge contact extends. In some embodiments, an edge contact may be communicatively coupled to one or more, all, or fewer than all conductive layers through which or between which the edge contact extends.

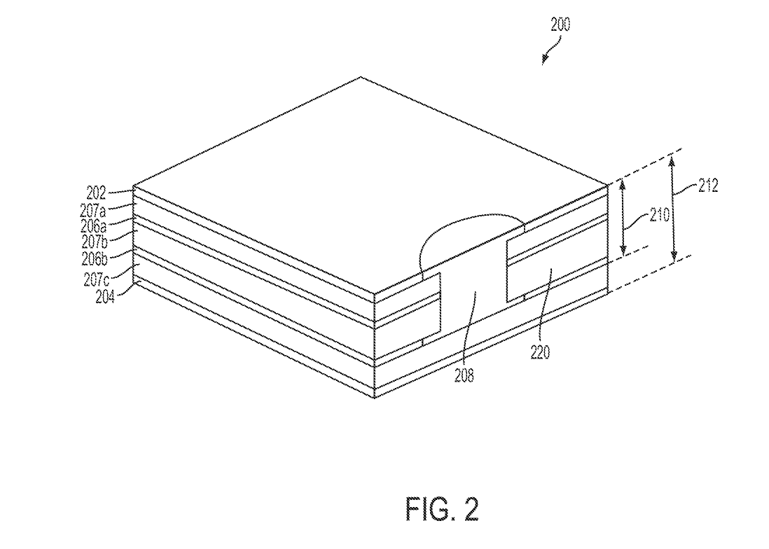

FIG. 2 shows a perspective view of a portion of a circuit board 200 with an edge contact 208, in accordance with some embodiments. Circuit board 200 includes seven layers (202, 204, 206a-b, and 207a-c). Top layer 202, bottom layer 204, and internal layers 206a-b may include conductive traces. Internal layers 207a-c may include a substrate that electrically insulates the conductive layers from each other.

Edge contact 208 is disposed at a peripheral edge 220 of circuit board 200. As shown in FIG. 2, the thickness 210 of edge contact 208 is less than the thickness 212 of peripheral edge 220. Edge contact 208 extends between top conductive layer 202 and internal conductive layer 206b, through internal conductive layer 206a, and through substrate layers 207a and 207b. The top end of edge contact 208 is exposed at top conductive layer 202. The bottom end of edge contact 208 is covered by internal substrate layer 207c and bottom layer 204. When the bottom end of an edge contact is covered by at least one layer of a circuit board, and the top end of the edge contact extends to or is exposed at a top layer 202 of the circuit board, as in the case of edge contact 208, the edge contact may be referred to as a “blind edge contact.” Likewise, when the top end of an edge contact is covered by at least one layer of a circuit board, and the bottom end of the edge contact extends to or is exposed at a bottom layer 204 of the circuit board, the edge contact may be referred to as a “blind edge contact.”

Edge contact 208 may be manufactured, for example, by forming a blind via hole in one or more layers of a circuit board, at least partially filling the blind via hole with a conductive material, and cutting the circuit board through at least a portion of the blind via hole to expose the conductive material. In the embodiment of FIG. 2, edge contact 208 may be communicatively coupled to components of top conductive layer 202 and internal conductive layer 206b. For example, the conductive material of edge contact 208 may be connected to conductive material (e.g., one or more traces) of top conductive layer 202 and internal conductive layer 206b.

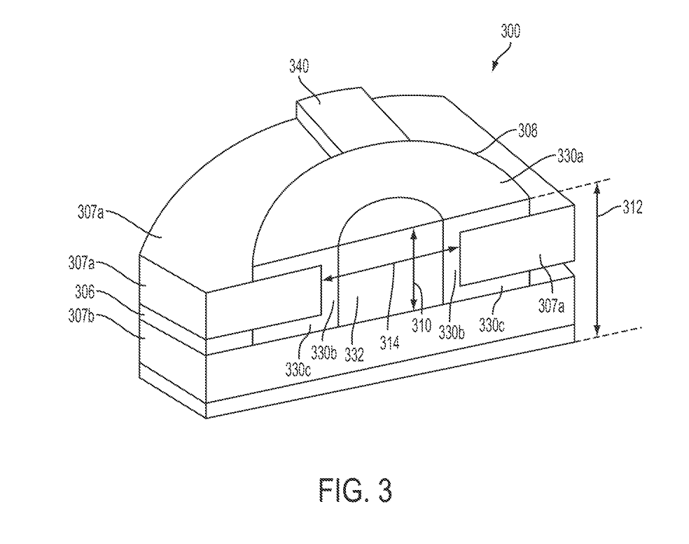

FIG. 3 shows a perspective view of a portion of a circuit board 300 with an edge contact 308, in accordance with some embodiments. Edge contact 308 is disposed at a peripheral edge of circuit board 300. As shown in FIG. 3, the thickness 310 of edge contact 308 is less than the thickness 312 of the circuit board's peripheral edge. Edge contact 308 extends from the circuit board's top layer, through substrate layer 307a, to an internal conductive layer 306. The bottom end of edge contact 308 is covered by substrate layer 307b and the circuit board's bottom layer. The top end of edge contact 308 is exposed at the circuit board's top layer, and is coupled to a trace 340.

Edge contact 308 may be manufactured, for example, by forming a blind via hole in one or more layers of a circuit board. In FIG. 3, the width (e.g., diameter) and depth of the via hole are designated by 314 and 310, respectively. In some embodiments, the width (e.g., diameter) of the via hole may be 0.015 inches, 0.020 inches, 0.028 inches, or any other width suitable for a via hole. In some embodiments, the depth of the via hole may be 0.008 inches, or any other depth suitable for a via hole.

The via hole may be plated with one or more plating materials to form plated portion 330 of edge contact 308. Plated portion 330 may include one or more conductive materials, such as copper or any suitable metallic material. In edge contact 308, plated portion 330 lines the interior of the via hole, forming a conductive plate 330b between the top and bottom of the hole. In some embodiments, conductive plate 330b may fully or partially line the interior of the via hole, forming a conductive path along the interior of the via hole.

In edge contact 308, plated portion 330 forms a border 330a at the top of edge contact 308, and a border 330c at the bottom of edge contact 308. Borders 330a and 330c may facilitate reliable electrical connections between edge contact 308 and other components of circuit board 300, such as traces. In FIG. 3, border 330a is connected to trace 340. In some embodiments, an edge contact may include a border at one or more circuit board layers to which or through which an edge contact extends, such as all or fewer than all conductive layers to which or through which the edge contact extends. In FIG. 3, border 330a is annular, but embodiments are not limited by the shape of a border of a plated portion of an edge contact. In some embodiments, an edge contact may not include a plated portion. In embodiments where an edge contact includes a plated portion, the plated portion may line at least a portion of the interior of the via hole and/or form a border for at least one end of the edge contact.

As shown, edge contact 308 may include a filling material 332. In some embodiments, filling material 332 may include a conductive material, such as copper, conductive epoxy, a metallic material, and/or any other suitable conductor. In some embodiments, filling material 332 may include a nonconductive material, such as nonconductive epoxy. Filling material 332 may fully or partially fill the portion of the via hole not filled by plated portion 330.

In some embodiments, plated portion 330 and/or filling material 332 may be surface plated. Surface plating may planarize the exposed surfaces of edge contact 308, increase the resistance of edge contact 308 to oxidation, and/or facilitate reliable electrical connection between edge contact 308 and other components of circuit board 300. In some embodiments, the surface plating may include electroless nickel immersion gold, solder, immersion silver, immersion tin, and/or any other material suitable for plating a via and/or an edge contact.

In FIG. 3, the side surface of edge contact 308 is flush with the surface of the peripheral edge at which edge contact 308 is disposed, and a central portion of the side surface of edge contact 308 is rectangular. Embodiments are not limited by the geometry of the side surface of an edge contact. In some embodiments, the side surface of an edge contact is recessed within a peripheral edge of circuit board 300. In some embodiments, the side surface of an edge contact protrudes from a peripheral edge of circuit board 300. The central portion of the side surface of edge contact 308 may be any suitable shape, including, but not limited to, rectangular, square, or triangular.

While FIG. 3 illustrates a blind edge contact, the descriptions of plating, filling, and/or finishing the blind edge contact also apply to a buried edge contact. A buried edge contact may include a plated portion 330 and/or a filling material 332. A buried edge contact may be finished or unfinished. A buried edge contact may be flush with a peripheral edge, be recessed in the peripheral edge, or protrude from the peripheral edge. A central portion of the side surface of a buried edge contact may be any suitable shape.

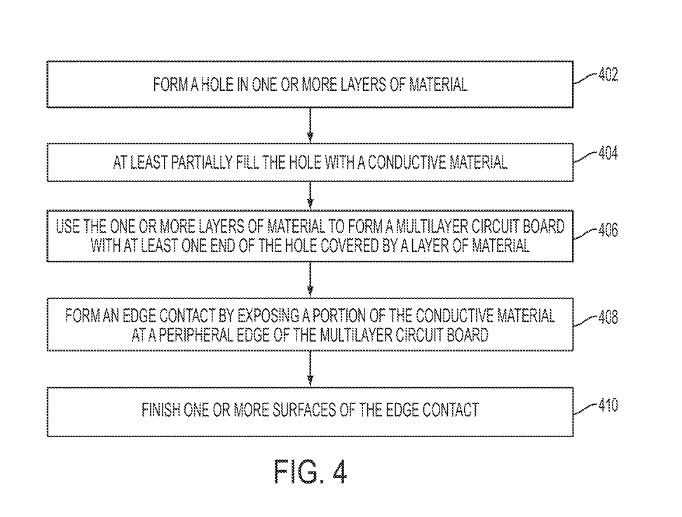

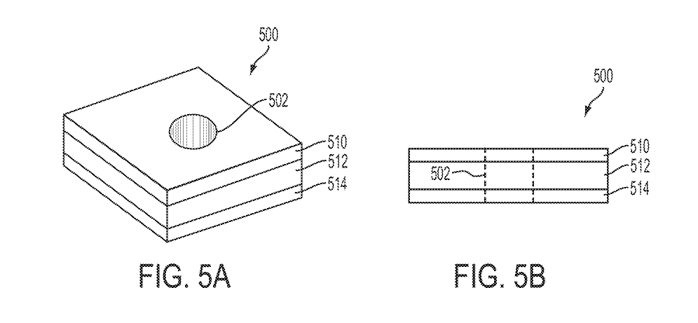

FIG. 4 shows a process for manufacturing a circuit board with an edge contact, in accordance with some embodiments. The following description of the process of FIG. 4 refers to FIGS. 5A-7B, which illustrate stages in the manufacturing of a circuit board with an edge contact, in accordance with some embodiments of the process of FIG. 4.

At step 402, a hole is formed in one or more layers of circuit board material, which may include one or more conductive layers, one or more substrate layers, and/or any other material layer(s) suitable for forming a circuit board. In the example of FIGS. 5A and 5B, hole 502 is a through-hole drilled through layers 510, 512, and 514 of circuit board 500, with layers 510 and 514 being conductive layers, and layer 512 being a substrate layer. In some embodiments, the hole may be formed by drilling, by etching, or by any other technique suitable for forming a hole or trench in one or more layers of circuit board materials. In some embodiments, the hole may be a via hole (e.g., a through-via hole or a microvia hole). In some embodiments, the hole and one or more via holes may be formed during the same circuit board fabrication step, using the same instrument(s) and/or technique(s). In some embodiments, the hole formed in the one or more layers of circuit board material may not be a through hole. For example, the hole formed in the one or more layers of material may be a microvia hole (e.g., a blind via hole or a buried via hole). Although the cross-sectional area of hole 502 is illustrated as being circular, in some embodiments the cross-sectional area of the hole may be square, rectangular, or any other suitable shape.

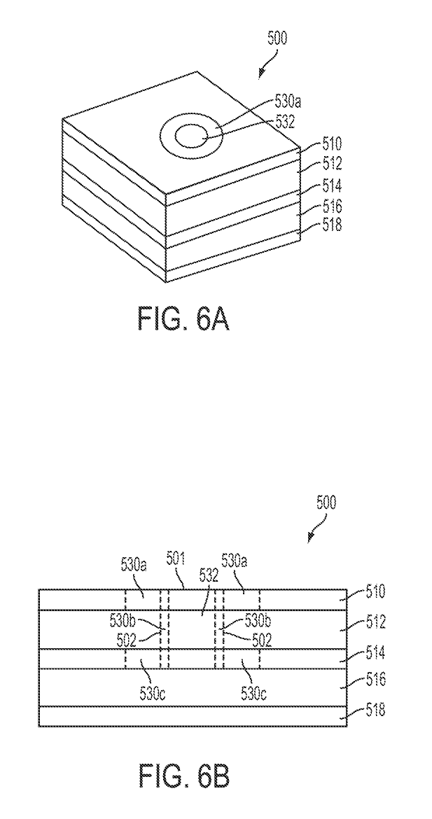

At step 404, the hole is at least partially filled with one or more conductive materials. At least partially tilling the hole with one or more conductive materials may comprise plating the hole to form a plated portion (e.g., at least partially lining the hole with one or more plating materials, such as copper), and/or depositing a filling material (e.g., copper, conductive epoxy, or nonconductive epoxy) in the hole. Any suitable technique for plating the hole and/or depositing a filling material in the hole may be used, as embodiments are not limited in this regard. In some embodiments, the one or more materials at least partially filling the hole may form a via. In some embodiments, the material(s) at least partially filling the hole and one or more vias may be formed during the same circuit board fabrication step, using the same instrument(s) and/or technique(s). In the example of FIGS. 6A and 6B, hole 502 is plated to form a top plated portion 530a, a bottom plated portion 530c, and a conductive plate 530b. Hole 502 is filled with a filling material 532.

At step 406, the one or more layers of material are used to form a multilayer circuit board with at least one end of the hole covered by a layer of material. In some embodiments, the one or more layers are attached to a covering layer that covers an end of the hole formed in step 402 and the via formed in step 404. In some embodiments, the one or more layers are attached to a second covering layer that covers a second end of the hole formed in step 402 and the via formed in step 404. A covering layer may include one or more substrate layers, one or more conductive layers, and/or one or more layers of any material suitable for forming a circuit board. A covering layer may be attached to the one or more layers using any suitable technique, including, but not limited to, laminating the one or more layers and the covering layer (e.g., applying pressure and heat to the one or more layers and the covering layer, such that the one or more layers and the covering layer bond to each other).

In the example of FIGS. 6A-6B, layers 510-514 are attached to layers 516-518, which cover a bottom end of via hole 502 and a bottom end of via 501. Layers 510-514 may be attached to layers 516-518 after hole 502 is formed by but before via 501 is formed, attached to layers 516-518 after via 501 is formed, or attached to layers 516-518 at any other suitable time. As can be seen, hole 502 is a blind via hole extending between layers 510 and 514, and through layer 512. Layer 516 may be a substrate layer, and layer 518 may be a conductive layer. Plated portion 530a-530c and filling material 532 collectively form blind via 501.

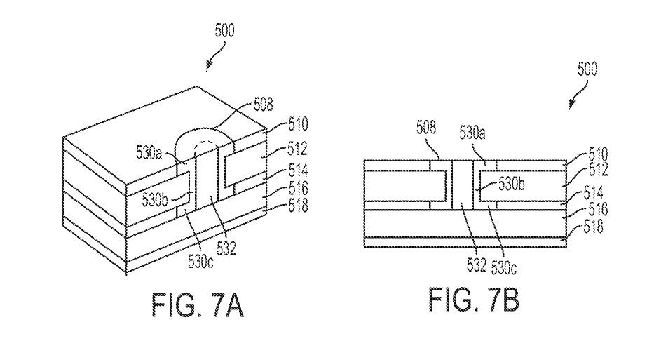

At step 408, an edge contact is formed by exposing, at a peripheral edge of the circuit board (or at a slot or edge that will become a peripheral edge of the circuit board), a portion of the one or more conductive materials formed in the hole at step 404. In some embodiments, exposing the conductive material(s) comprises cutting the circuit board to form a slot or a peripheral edge through the hole, through the via formed in the hole, and/or through at least a portion of the conductive materials formed in the hole. A slot may include a recess or a hole in the circuit board, or a hole through the circuit board, in a direction of the thickness of the circuit board. Cutting the circuit board to form an edge or slot may be performed using any suitable instrument or technique, including, but not limited to, using a router to route the edge or slot. In the example of FIGS. 7A-7B, circuit board 500 has been cut to form a peripheral edge through hole 502 and through via 532, thereby exposing a side of edge contact 508 along the peripheral edge of the circuit board.

At step 410, one or more exposed surfaces of the edge contact are finished (e.g., surface plated). Any suitable technique for finishing the edge contact may be used. In some embodiments, finishing the edge contact may comprise surface plating the edge contact with electroless nickel immersion gold, solder, immersion silver, immersion tin, and/or any other material suitable for plating a via. In some embodiments, finishing the one or more exposed surfaces of the edge contact and finishing a surface of a via may be performed in a same manufacturing step and/or using a same manufacturing technique.

### Further Description of Some Embodiments

Although the flowchart of FIG. 4 depicts a sequential ordering among steps 402-410 of the process for manufacturing a circuit board with an edge contact, steps 402-410 may be performed in any order suitable for manufacturing a printed circuit board. In some embodiments, the one or more layers in which the hole is formed may be covered by a covering layer before the hole is formed (e.g., step 406 may be performed before steps 402 and 404), or before the hole is at least partially filled with a conductive material (e.g., step 406 may be performed after step 402 and before step 404). In some embodiments, steps 402-406 may be replaced by an suitable process for forming a microvia (e.g., a blind via or a buried via) in a circuit board. In some embodiments, step 410 may be performed after step 404 but before steps 406 and 408, such that top and bottom ends of the edge contact are finished, but a side surface of the edge contact is not finished. In some embodiments, step 410 may be performed after step 406 but before step 408, such that one end of the edge contact is finished, but the other end of the edge contact and the side surface of the edge contact are not finished. In some embodiments, some of the steps illustrated in FIG. 4 may be omitted. For example, the step of finishing one or more surfaces of the edge contact may be omitted in some embodiments. In some embodiments, some of the steps illustrated in FIG. 4 (or at least some portions of some of the steps illustrated in FIG. 4) may be performed simultaneously or in parallel.

Although FIGS. 5A-7B illustrate the process of FIG. 4 being used to form a blind edge contact, the process of FIG. 4 may also be used to form a buried edge contact.

Some embodiments of the above-described edge contacts may provide superior signal quality, relative to conventional edge contacts. In some embodiments, the size (e.g., surface area, length, and/or width) of an edge contact may be controlled to aid in low-loss signal propagation at higher frequencies. For example, an edge contact's dimensions may be configured to reduce signal loss by reducing reflections associated with abrupt geometry changes along the signal line at interconnection sites. In some embodiments, the cross-sectional dimensions (e.g., length and/or width) of an edge contact may be configured to match the cross-sectional dimensions of one or more signal carriers (e.g., traces, vias, and/or wires) to which the edge contact is communicatively coupled. A dimension of an edge contact may “match” a corresponding dimension of a signal carrier when the difference between the edge contact's dimension and the signal carrier's corresponding dimension is less than approximately 25%, 20%, 15%, 10%, 5%, 3%, 2%, 1%, 0.1%, or 0.01%. The cross-sectional dimensions of an edge contact may “match” the corresponding cross-sectional dimensions of a signal carrier when the signal loss at the boundary between the edge contact and the signal carrier is less than approximately 3 dB, 2 dB, 1 dB, 0.5 dB, 0.1 dB, 0.05 dB, 0.01 dB, 0.005 dB, or 0.001 dB. In some embodiments, multiple edge contacts may be fabricated along an edge of a circuit board to accommodate multiple circuit interconnections including, but not limited to, differential pairs.

The above-described edge contact and manufacturing technique have been described as being suitable for sensor applications. Some embodiments are not limited in this regard. Some embodiments may, for example, additionally or alternatively be used for secure processing, data security, anti-tampering, intellectual property protection, and/or for any other suitable application.

In some embodiments, one or more edge contacts on a first circuit board may be coupled to one or more edge contacts on a second circuit board. For example, the first and second circuit boards may be disposed in a tiled configuration, with the edge contacts used for communication between the circuit boards. Any number of circuit boards may be tiled in this manner.

In some embodiments, an edge pad may be formed by routing a conductive trace to a peripheral edge of a circuit board (e.g., by cutting the circuit board to form the peripheral edge at a location which transects a conductive trace), and by forming an edge pad connected to the conductive trace. The edge pad may, for example, be formed by sputtering a conductive material (e.g., a metallic material) onto the peripheral edge at the position of the conductive trace, by pasting a conductive pad to the peripheral edge at the position of the conductive trace (e.g., with a conductive paste), or by plating a portion of the peripheral edge and etching away the plated portion to form a pad at the position of the conductive trace.

In some embodiments, a buried via hole may be filled by plating the hole and filling some or all of the remaining portion of the hole with a conductive or nonconductive material. In other embodiments, a buried via hole may be filled by filling some or all of the hole with a conductive material, without first plating the hole.

It should be understood that the various embodiments shown in the Figures are illustrative representations, and are not necessarily drawn to scale. Reference throughout the specification to “one embodiment” or “an embodiment” or “some embodiments” means that a particular feature, structure, material, or characteristic described in connection with the embodiment(s) is included in at least one embodiment, but not necessarily in all embodiments. Consequently, appearances of the phrases “in one embodiment,” “in an embodiment,” or “in some embodiments” in various places throughout the Specification are not necessarily referring to the same embodiment.

Unless the context clearly requires otherwise, throughout the disclosure, the words “comprise,” “comprising,” and the like are to be construed in an inclusive sense as opposed to an exclusive or exhaustive sense; that is to say, in a sense of “including, but not limited to.” Additionally, the words “herein,” “hereunder,” “above,” “below,” and words of similar import refer to this disclosure as a whole and not to any particular portions of this disclosure. When the word “or” is used in reference to a list of two or more items, that word covers all of the following interpretations of the word: any of the items in the list; all of the items in the list; and any combination of the items in the list.

Having thus described several aspects of at least one embodiment of the technology, it is to be appreciated that various alterations, modifications, and improvements will readily occur to those skilled in the art. Such alterations, modifications, and improvements are intended to be within the spirit and scope of the technology. Accordingly, the foregoing description and drawings provide non-limiting examples only.

1. A circuit board, comprising:
a plurality of layers stacked in a thickness direction;
a peripheral edge having a first thickness in the thickness direction; and
an edge contact disposed at the peripheral edge of the circuit board, the edge contact having a second thickness in the thickness direction, the second thickness being less than the first thickness.

2. The circuit board of claim 1, wherein the first thickness of the peripheral edge extends from a first surface of the circuit board to a second surface of the circuit board, and wherein the second thickness of the edge contact does not extend to the first surface of the circuit board.

3. The circuit board of claim 2, wherein the second thickness of the edge contact does not extend to the second surface of the circuit board.

4. The circuit board of claim 3, wherein the edge contact comprises at least a portion of a buried via.

5. The circuit board of claim 2, wherein the second thickness of the edge contact extends to the second surface of the circuit board.

6. The circuit board of claim 5, wherein the edge contact comprises at least a portion of a blind via.

7. The circuit board of claim 1, wherein the first surface of the circuit board comprises a top surface of the circuit board, and wherein the second surface of the circuit board comprises a bottom surface of the circuit board.

8. The circuit board of claim 1, wherein the plurality of layers includes a top layer, a bottom layer, and an internal layer disposed between the top and bottom layers, wherein the first thickness of the peripheral edge extends from an upper surface of the top layer to a lower surface of the bottom layer, and wherein the second thickness of the edge contact does not extend to the upper surface of the top layer.

9. The circuit board of claim 8, wherein the second thickness of the edge contact does not extend to the lower surface of the bottom layer.

10. The circuit board of claim 9, wherein the edge contact comprises at least a portion of a buried via.

11. The circuit board of claim 9, wherein the second thickness of the edge contact extends to the lower surface of the bottom layer.

12. The circuit board of claim 11, wherein the edge contact comprises at least a portion of a blind via.

13. A method of manufacturing a circuit board, comprising:
at least partially filling a hole with a conductive material, the hole extending through one or more layers of material;
using the one or more layers of material to form a multilayer circuit board with at least one end of the hole covered by a layer of material; and
forming an edge contact by exposing a portion of the conductive material at a peripheral edge of the multilayer circuit board.

14. The method of claim 13, wherein using the one or more layers of material to form a multilayer circuit board with at least one end of the hole covered by a layer of material comprises attaching the layer of material to the one or more layers of material, the layer of material covering a first end of the hole.

15. The method of claim 14, wherein the hole and the conductive material form a blind via.

16. The method of claim 14, wherein the layer of material is a first layer, and wherein using the one or more layers of material to form a multilayer circuit board with at least one end of the hole covered by a layer of material further comprises attaching a second layer to the one or more layers of material, the second layer covering a second end of the hole.

17. The method of claim 16, wherein the hole and the conductive material form a buried via.

18. The method of claim 13, wherein exposing the portion of the conductive material at the peripheral edge of the multilayer circuit board comprises cutting the multilayer circuit board through the at least partially filled hole to form the peripheral edge.

19. The method of claim 16, wherein cutting the multilayer circuit board through the at least partially filled hole comprises routing the multilayer circuit board through the at least partially filed hole.

20. The method of claim 13, further comprising plating and/or finishing the exposed portion of the conductive material.
